(19) United States
(12) Patent Application Publication
(10) Pub. No.: US 2015/0060811 A1
(43) Pub. Date: Mar. 5, 2015

(54) LIGHT EMITTING APPARATUS AND ELECTRONIC APPARATUS

(71) Applicant: SEIKO EPSON CORPORATION, Tokyo (JP)

(72) Inventor: Koya SHIRATORI, Matsumoto-shi (JP)

(21) Appl. No.: 14/463,152

(22) Filed: Aug. 19, 2014

(30) Foreign Application Priority Data
Aug. 28, 2013 (JP) 2013-176381

(51) Int. Cl. H01L 51/52; H01L 27/32

(52) U.S. Cl. CPC H01L 51/5265; H01L 51/5271; H01L 27/3206
USPC 257/40

(57) ABSTRACT

In the light emitting apparatus having a resonance structure for adjusting an optical path length between the reflecting layer and the translucent reflecting layer, in which the emitting layer performs internal luminescence on a first wavelength region and a second wavelength region on a short wavelength side with respect to the first wavelength region, in the second wavelength region, a light emitting peak wavelength, a resonance peak wavelength, and an output wavelength satisfy a relationship of the light emitting peak wavelength>the output wavelength>the resonance peak wavelength, and film thicknesses of an array cavity layer and the emitting layer are adjusted so that an emission intensity of the output wavelength is equal to or less than 15% of an emission intensity of the output wavelength.

### BACKGROUND

1. Technical Field

The invention relates to a light emitting apparatus using various kinds of light emitting devices and an electronic apparatus including the light emitting apparatus.

2. Related Art

In recent years, organic EL (electro luminescence) devices have been formed on a substrate as a light emitting device, and a top emission-type light emitting apparatus that extracts emission light of the light emitting device to the opposite side of the substrate has been widely used as a display apparatus of an electronic apparatus. The top emission scheme is a scheme of interposing a light emitting device, forming a reflecting layer between a first electrode (for example, an anode) on one side formed on a substrate side and a substrate, and extracting light from a second electrode (for example, a cathode) side on the other side interposing the light emitting device, and is a scheme having high utilization efficiency of light.

In the top emission-type light emitting apparatus, a method of using a white organic EL device, and adjusting resonance lengths in respective red, green, and blue pixels with film thicknesses of a transparent film and a transparent electrode film formed on the substrate side is suggested (see Japanese Patent No. 2797883).

In the light emitting apparatus, if an optical distance between a reflecting layer and a second electrode is D, a phase shift in the reflection on a reflecting layer 12 is φ_{L}, a phase shift in the reflection on the second electrode is φ_{U}, a peak wavelength of a standing wave is λ, and an integer is m, and the structure satisfies the following equation.

D={(2πm+φ_{L}+φ_{U})/4π}λ (1)

In the structure, it is possible not only to enhance light extraction efficiency, but also to enhance the color purity, and to realize high quality display. Also, in the resonance structure alone, the color purity is insufficient and it is not possible to realize a display having good color reproductivity, and thus a color filter may be added (for example, Japanese Patent No. 4403399).

However, Equation (1) described above, when m=1 is set and red, green, and blue pixels are configured in the red pixel, not only an original red wavelength component, but also a blue wavelength component on a short wavelength side is extracted. Therefore, when a color filter is not used, the color reproductivity is deteriorated. Also, even if a color filter is added in order to remove a blue component on the short wavelength side, when compared with a case in which only red light is output, it is necessary to form a color filter having a thick film thickness, and the brightness may decrease, or the cost may increase.

### SUMMARY

In view of the circumstances, an advantage of some aspects of the invention is the prevention of decrease in the color reproductivity without using a color filter by combining an organic EL device and a resonance structure.

According to an aspect of the invention, there is provided a light emitting apparatus including a substrate; a reflecting layer disposed on the substrate; an array cavity layer that includes a transparent layer disposed on the reflecting layer and a transparent electrode layer disposed on the transparent layer; an emitting layer disposed on the array cavity layer; and a translucent reflecting layer disposed on the emitting layer, in which a resonance structure of adjusting an optical path length between the reflecting layer and the translucent reflecting layer is included for each emission region, and the emitting layer performs internal luminescence on a first wavelength region and a second wavelength region on a short wavelength side with respect to the first wavelength region, when a light emitting peak wavelength of the first wavelength region in the internal luminescence is λ_{LIN}, the resonance peak wavelength of the first wavelength region in the resonance is λ_{LC}, an output wavelength of the first wavelength region is λ_{LOUT}, a light emitting peak wavelength of the second wavelength region in the internal luminescence is λ_{SIN}, a resonance peak wavelength of the second wavelength region in the resonance is λ_{SC}, and an output wavelength of the second wavelength region is λ_{SOUT} the light emitting peak wavelength λ_{LIN} of the first wavelength region the resonance peak wavelength λ_{LC} of the first wavelength region, and the output wavelength λ_{LOUT} of the first wavelength region are substantially identical, and the light emitting peak wavelength λ_{SIN} of the second wavelength region, the resonance peak wavelength λ_{SC} of the second wavelength region, and the output wavelength λ_{SOUT} of the second wavelength region satisfy a relationship of light emitting peak wavelength λ_{SIN}>output wavelength λ_{SOUT}>resonance peak wavelength λ_{SC}, and film thicknesses of the array cavity layer and the emitting layer are adjusted so that an emission intensity of the output wavelength λ_{SOUT} represented by a product of an emission intensity of the light emitting peak wavelength λ_{SIN} and an emission intensity of the resonance peak wavelength λ_{SC} is equal to or less than 15% of an emission intensity of the output wavelength λ_{LOUT}.

In this case, since the film thicknesses of the array cavity layer and the emitting layer are adjusted so that an emission intensity of the output wavelength λ_{SOUT} of the second wavelength region on the long wavelength side is equal to or less than 15% of the emission intensity of the output wavelength λ_{LOUT} of the first wavelength region on the short wavelength side, the emission light of the output wavelength λ_{SOUT} of the second wavelength region on the long wavelength side is hardly extracted, and a wide color gamut can be realized without using a color filter.

In the light emitting apparatus described above, when an optical path length of the translucent reflecting layer from the reflecting layer is D(λ), a phase shift in reflection on the reflecting layer is φ_{L}(λ), a phase shift in reflection on the translucent reflecting layer is φ_{U}(λ), a peak wavelength of a standing wave generated between the reflecting layer and the translucent reflecting layer is 2, and an integer equal to or smaller than 2 is m, the resonance peak wavelength λ_{LC} of the first wavelength region may satisfy

λ_{LC}=D(λ_{LC})/{(2πm+φ_{L}(λ_{LC})+φ_{U}(λ_{LC}))/4π} (2), and

the resonance peak wavelength λ_{SC} of the second wavelength region may satisfy

λ_{SC}=D(λ_{SC})/{(2π)(m+1)+φ_{L}(λ_{SC})+φ_{U}(λ_{SC}))/4π} (3),

and when a predetermined constant is B, the resonance peak wavelength λ_{SC} and the light emitting peak wavelength λ_{SIN} may satisfy resonance peak wavelength λ_{SC}≦light emitting peak wavelength λ_{SIN}−B. In this case, since the resonance peak wavelength λ_{SC} and the light emitting peak wavelength λ_{SIN} satisfy resonance peak wavelength λ_{SC}≦light emitting peak wavelength λ_{SIN}−B, the emission light of the output wavelength λ_{SOUT} of the second wavelength region on the long wavelength side is hardly extracted, and a wide color gamut can be realized without using a color filter.

In the light emitting apparatus described above, with respect to the resonance peak wavelength λ_{LC} and the resonance peak wavelength λ_{SC}, the optical path length D(λ_{LC}) and the optical path length D(λ_{SC}) may be adjusted so that the integer m becomes 1 in the equations of the optical path length D(λ_{LC}) and the optical path length D(λ_{SC}). In this case, when the integer m is 1, light emission efficiency, color purity, and manufacturability are enhanced, and a wide color gamut can be realized without using a color filter.

In the light emitting apparatus described above, the constant B may be set to 30 nm. In this case, the emission light of the output wavelength λ_{SOUT} of the second wavelength region on the long wavelength side is rarely extracted, and a wide color gamut can be realized without using a color filter.

In the light emitting apparatus described above, an extinction coefficient in the emitting layer may be equal to or greater than 0.02 in the resonance peak wavelength λ_{SC}. In this instance, the light on the reflecting layer and the counter electrode are absorbed while reflection repeats. Accordingly, as the resonance peak wavelength λ_{SC} on the short wavelength side is shifted to the short wavelength side, the intensity of the resonance spectrum decreases. Since the output wavelength λ_{OUT} is obtained by the product of the emission intensity of the internal luminescence and the intensity of the resonance spectrum, if the intensity of the resonance peak wavelength λ_{SC} on the short wavelength side decreases, the extracted short wavelength component becomes small. Accordingly, it is possible to enhance the color purity of the red pixel.

In the light emitting apparatus described above, the resonance peak wavelength λ_{SC} may be equal to or less than 450 nm. In this instance, the resonance peak wavelength λ_{SC} on the short wavelength side is shifted to the short wavelength side, and the intensity of the resonance spectrum also decreases. Since the output wavelength λ_{OUT} is obtained by the product of the emission intensity of the internal luminescence and the intensity of the resonance spectrum, if the intensity of the resonance peak wavelength λ_{SC} on the short wavelength side decreases, the extracted short wavelength component becomes small. Accordingly, it is possible to enhance the color purity of the red pixel.

According to another aspect of the invention, there is provided an electronic apparatus including the light emitting apparatus. In the electronic apparatus, since the light emitting apparatus is included, it is possible to provide the electronic apparatus having a display unit with a wide color gamut.

The electronic apparatus may include an optical member between an emitting surface of the light emitting apparatus and a display surface of the electronic apparatus. According to the electronic apparatus of the invention, good display having a wide color gamut is exhibited.

### BRIEF DESCRIPTION OF THE DRAWINGS

The invention will be described with reference to the accompanying drawings, wherein like numbers reference like elements.

FIG. 1 is a cross-sectional view schematically illustrating a concept of a light emitting apparatus according to an embodiment of the invention.

FIG. 2 is a diagram illustrating materials used in an emitting layer in a light emitting function layer.

FIG. 3 is a graph illustrating chromaticity of red pixels in the respective light emitting apparatuses according to Comparison example 1, and Examples 1 to 3.

FIG. 4 is a graph illustrating emission spectrums of the red pixels in the respective light emitting apparatuses according to Comparison example 1, and Examples 1 to 3.

FIG. 5 is a diagram illustrating changes in the refractive indexes of wavelengths with respect to HT-320 used in a hole injection layer and hole transport layer, and SiN and SiO₂ used in a transparent layer.

FIGS. 6A and 6B are diagrams illustrating differences of resonance components when film thicknesses of a hole injection layer and a transparent layer are changed, FIG. 6A is a diagram illustrating the resonance component when the hole injection layer is thick and the transparent layer is thin, and FIG. 6B is a diagram illustrating the resonance component when the hole injection layer is thin and the transparent layer is thick.

FIG. 7 is a diagram illustrating an emission spectrum inside a white light emitting function layer and simulation results of resonance spectrums according to Comparison example 1, and Examples 1 to 3.

FIG. 8 is a diagram illustrating a change of an extinction coefficient with respect to the wavelength of the light emitting function layer.

FIG. 9 is a perspective view illustrating a micro display according to Application example 1.

FIG. 10 is a perspective view illustrating a head-mounted display according to Application example 1.

FIG. 11 is a diagram illustrating an optical configuration of the head-mounted display according to Application example 1.

FIG. 12 is a perspective view illustrating a configuration of a mobile personal computer according to Application example 2.

FIG. 13 is a perspective view illustrating a configuration of a cellular phone according to Application example 2.

FIG. 14 is a perspective view illustrating a configuration of a portable information terminal according to Application example 2.

### DESCRIPTION OF EXEMPLARY EMBODIMENTS

Hereinafter, various exemplary embodiments according to the invention are described with reference to the accompanied drawings. In the drawings, ratios of respective elements in size are suitably different from actual elements.

### A: Structure of Light Emitting Apparatus

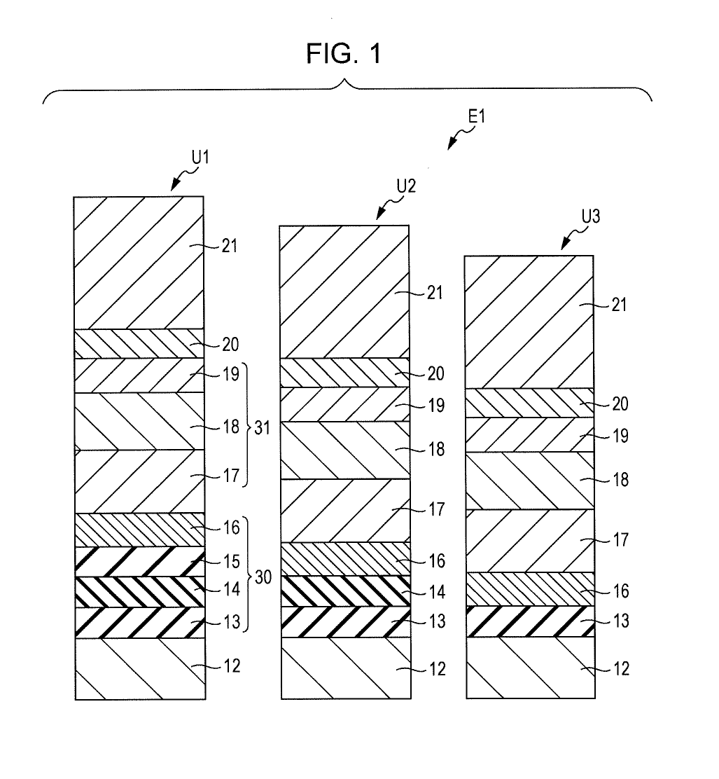

FIG. 1 is a cross-sectional view schematically illustrating a concept of a light emitting apparatus E1 according to an embodiment of the invention. The light emitting apparatus E1 has a configuration in which a plurality of light emitting devices U1, U2, and U3 are arranged on a surface of a first substrate (not illustrated). However, in FIG. 1, for convenience of explanation, the light emitting devices U1, U2, and U3 having respectively colors of red, green, and blue are illustrated one by one. The light emitting apparatus E1 according to the embodiment is a top emission type, and light generated from the light emitting devices U1, U2, and U3 proceeds to an opposite side to the first substrate. Accordingly, in addition to a plate material having optical transparency such as glass, an opaque plate material such as a ceramic sheet or a metal sheet can be employed as the first substrate.

Further, wiring lines for causing the light emitting devices U1, U2, and U3 to emit light by supplying electricity and circuits for causing the light emitting devices U1, U2, and U3 to emit light by supplying electricity are not illustrated in the drawings.

The red light emitting device U1 includes the reflecting layer 12, a first transparent layer 13 formed on the reflecting layer 12, a second transparent layer 14 formed on the first transparent layer 13, and a third transparent layer 15 formed on the second transparent layer 14. Also, the red light emitting device U1 includes a transparent electrode layer (pixel electrode, anode) 16 formed on the third transparent layer 15. The array cavity layer 30 is configured with the first transparent layer 13, the second transparent layer 14, the third transparent layer 15, and a transparent electrode layer 16.

Also, the red light emitting device U1 has a hole injection layer and hole transport layer 17 formed on the transparent electrode layer 16, an emitting layer 18 formed on the hole injection layer and hole transport layer 17, and an electron transport layer 19 formed on the emitting layer 18. The hole injection layer and hole transport layer 17, the emitting layer 18, and the electron transport layer 19 configure a light emitting function layer 31. Furthermore, the red light emitting device U1 includes a counter electrode 20 (cathode) formed on the electron transport layer 19 as a light ejection-side translucent transflective layer, and a sealing layer 21 formed on the counter electrode 20.

The green light emitting device U2 and the blue light emitting device U3 also have substantially the same configurations, but are different from the red light emitting device U1 in that the green light emitting device U2 includes the first transparent layer 13 and the second transparent layer 14, and the blue light emitting device U3 has the first transparent layer 13 only. That is, in the red light emitting device U1, the green light emitting device U2, and the blue light emitting device U3, an optical distance from the reflecting layer 12 to the counter electrode 20 is adjusted by the number of stacked transparent layers.

The reflecting layer 12 is formed of a material having optical reflectivity. As this kind of material, simple metal such as aluminum (Al), silver (Ag), gold (Au), copper (Cu), and an alloy including Al, Au, Cu, or Ag, as a main component are suitably employed. According to the embodiment, the reflecting layer 12 is formed of Al. According to the embodiment, the film thickness of the reflecting layer 12 is 150 nm.

The first transparent layer 13, the second transparent layer 14, and the third transparent layer 15 are formed on the reflecting layer 12. These transparent layers are formed of SiO₂ or SiN. According to the embodiment, the first transparent layer 13 is formed of SiN, has a film thickness of 70 nm. Also, the second transparent layer 14 is formed of SiO₂, and has a film thickness of 40 nm. In addition, the third transparent layer 15 is formed of SiO₂, and has a film thickness of 45 nm.

The transparent electrode layer 16 is formed of ITO. According to the embodiment, the film thickness of the transparent electrode layer 16 is 20 nm. The transparent electrode layer 16 is separated from a red (R) transparent electrode layer for the light emitting device, a green (G) transparent electrode layer for the light emitting device, and a blue (B) transparent electrode layer for the light emitting device by an insulating layer (not illustrated).

The hole injection layer (HIL) and hole transport layer (HTL) 17 is formed with HT-320 (manufactured by IDEMITSU KOSAN Co., Ltd.). According to the embodiment, the film thickness of the hole injection layer and hole transport layer 17 is 60 nm. Further, the hole injection layer and hole transport layer 17 is formed as a single layer having both the hole injection layer function and the hole transport layer function, but may be formed as respectively different layers. When the hole injection layer and hole transport layer 17 is formed as different layers, for example, the hole injection layer may be formed of MoOx (molybdenum oxides), and the hole transport layer may be formed of α-NPD.

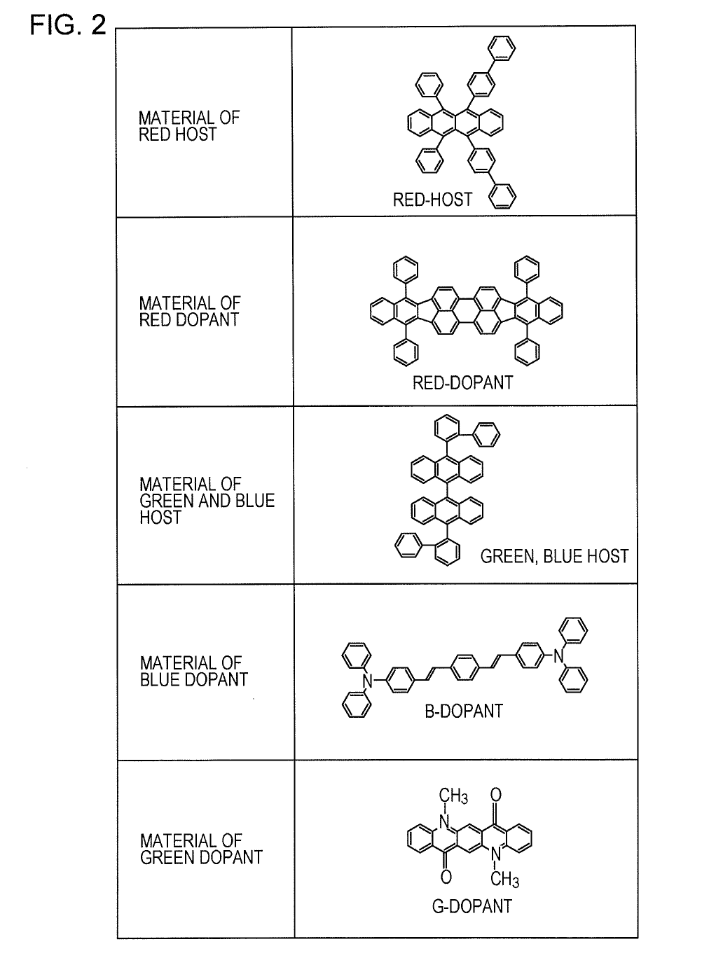

The emitting layer (EML) 18 is formed from an organic EL substance in which holes and electrons are combined to emit light. According to the embodiment, the organic EL substance is a low molecular weight material, and emits white light. Materials illustrated in FIG. 2 are used for a red host material, a red dopant material, and green and blue host materials. Furthermore, DPAVBi is used for a blue dopant material. Quinacridone is used for a green dopant material. According to the embodiment, the film thickness of the emitting layer is 45 nm.

The electron transport layer (ETL) 19 is formed with Alq3 (tris 8-quinolinolato aluminum complex). According to the embodiment, the film thickness of the electron transport layer is 25 nm.

The counter electrode 20 is a cathode, and is formed to cover a light emitting function layer formed with the hole injection layer and hole transport layer 17, the emitting layer 18, and the electron transport layer 19. The counter electrode 20 is provided throughout the plurality of light emitting devices U1, U2, and U3. The counter electrode 20 functions as a translucent reflecting layer having a characteristic of causing a portion of the light to penetrate to reach a surface thereof and reflecting another portion of the light (that is, a translucent transflective property), and is formed of simple metal such as magnesium and silver, or an alloy including magnesium or silver, as a main component. According to the embodiment, the counter electrode 20 is formed of a magnesium-silver alloy (MgAg). The film thickness of the counter electrode 20 is 20 nm.

The sealing layer 21 is a protective layer for protecting the light emitting devices U1, U2, and U3 from the infiltration of water or outside air, and is formed of an inorganic material having low gas permeability such as silicon nitride (SiN) or silicon oxynitride (SiON). According to the embodiment, the sealing layer 21 is formed of SiON, and has a film thickness of 1 μm.

The light emitting apparatus E1 according to the embodiment employs a resonance structure that generates a standing wave from the reflecting layer 12 to the counter electrode 20 by setting the optical distance from the reflecting layer 12 to the counter electrode 20 as the light ejection-side translucent reflecting layer to a predetermined value.

Specifically, when the optical distance from the emitting layer 18 side of the reflecting layer 12 to the emitting layer 18 side of the counter electrode 20 is D, a phase shift in the reflection on the reflecting layer 12 is φ_{L}, a phase shift in the reflection on the counter electrode 20 is φ_{U}, a peak wavelength of a standing wave is A, and an integer is m, the structure satisfies the following equation.

D={(2πm+φ_{L}+φ_{U})/4π}λ (4)

The light emitting apparatus E1 according to the embodiment specifically has a structure of setting m=1 in Equation (4) described above, adjusting the optical distance D by the film thickness of the transparent layer, and reading colors of red, green, and blue wavelengths.

### <B: Chromaticity Comparison of Red Pixel>

In the light emitting apparatus E1 according to the embodiment and the light emitting apparatus according to the comparison example as described below, the result obtained by performing chromaticity comparison on the red pixel is described. Further, 3 kinds of light emitting apparatuses according to Examples 1 to 3 in which a film thickness of the hole injection layer and hole transport layer 17, and a film thickness of the first transparent layer 13 are respectively changed are used as the light emitting apparatus E1 according to the embodiment compared to the light emitting apparatus according to the comparison example. Detailed descriptions are provided below.

### B-1: Film Thicknesses According to Comparison Example 1, and Examples 1 to 3

The light emitting apparatuses according to Comparison example 1, and Examples 1 to 3 have layers having the same structures as the light emitting apparatus according to the embodiment described above, but have different film thicknesses of the hole injection layer and hole transport layers 17 and different film thicknesses of the first transparent layers 13. Table 1 shows film thicknesses of the hole injection layer and hole transport layers 17 according to Comparison example 1, and Examples 1 to 3, and film thicknesses of the first transparent layers 13.

TABLE 1

| | Film thickness of | Film thickness of |
|---|---|---|
| | hole injection | first transparent |
| | layer [nm] | layer [nm] |
| Comparison example 1 | 80 | 58 |
| Example 1 | 60 | 70 |
| Example 2 | 40 | 82 |
| Example 3 | 20 | 96 |

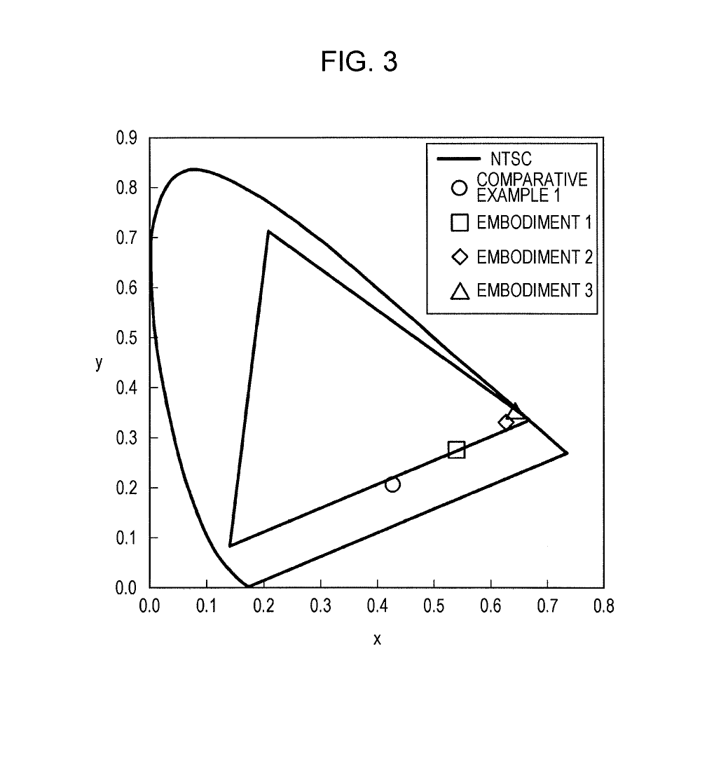

FIG. 3 is a graph illustrating results obtained by comparing red pixels in the respective light emitting apparatuses according to Comparison example 1, and Examples 1 to 3. As illustrated in FIG. 3, Comparison example 1 has the lowest chromaticity, and subsequently red chromaticity becomes higher in a sequence of Examples 1 to 3. That is, it is found that as the film thickness of the hole injection layer and hole transport layer 17 becomes thinner, and the film thickness of the first transparent layer becomes thicker, red chromaticity becomes higher.

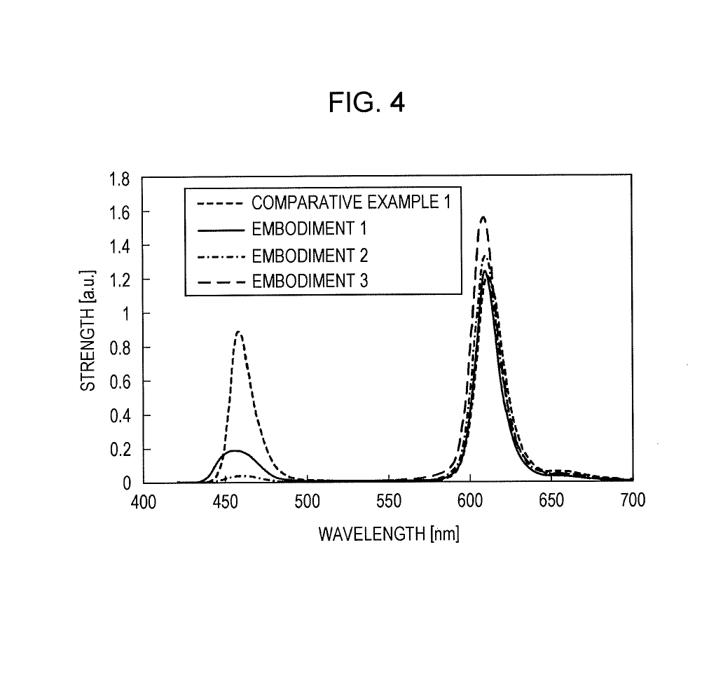

FIG. 4 is a graph illustrating results obtained by examining emission spectrums of the red pixels in the respective light emitting apparatuses according to Comparison example 1, and Examples 1 to 3. As illustrated in FIG. 4, it is found that a blue wavelength component (460 nm to 470 nm) is read at a comparatively high intensity in the red pixel according to Comparison example 1. However, the intensities of blue wavelength components in Examples 1 to 3 are low, and a blue wavelength component is rarely read in Example 3. That is, it is found that it is possible to cause a red pixel to have high color purity in Examples 1 to 3.

### <C: Principle of the Invention>

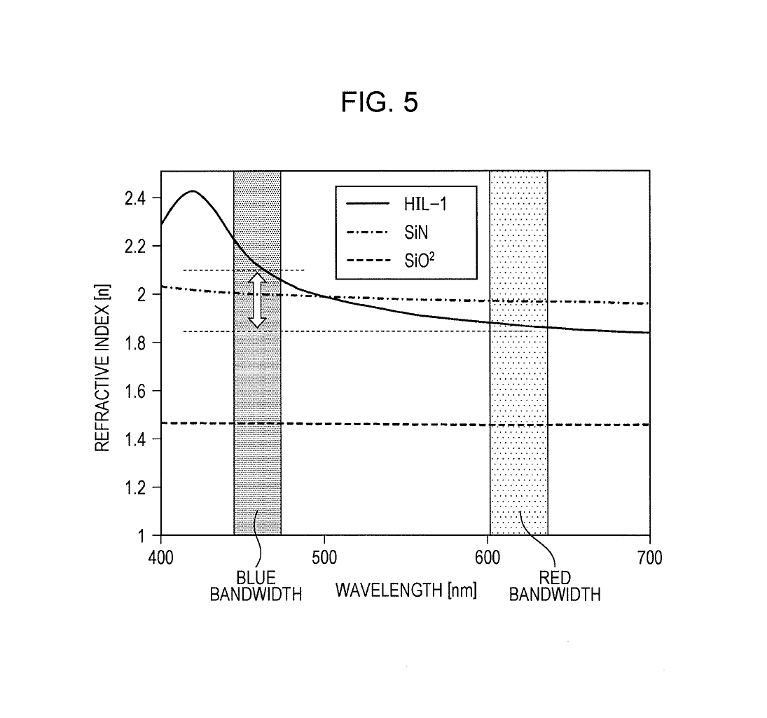

FIG. 5 is a diagram illustrating a result obtained by examining changes of refractive indexes of wavelengths with respect to HT-320 used in the hole injection layer and hole transport layer, and SiN and SiO₂ used in the transparent layer. As illustrated in FIG. 5, it is found that refractive indexes with respect to SiN and SiO₂ used in the transparent layer are substantially flat. However, with respect to HT-320, it is found that the refractive indexes in the blue bandwidth and on the shorter frequency side than the blue bandwidth are extremely higher than the refractive index in the red bandwidth.

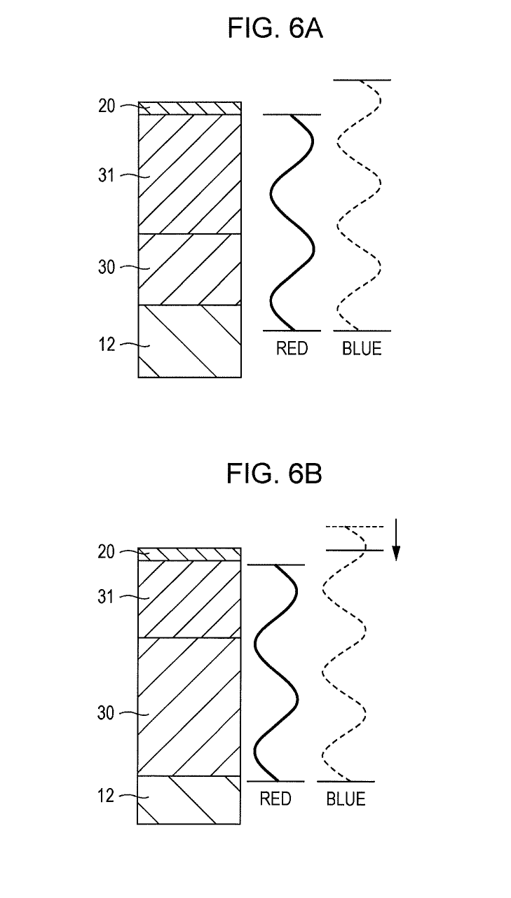

FIGS. 6A and 6B are diagrams illustrating differences of resonance components when film thicknesses of the hole injection layer and the transparent layer are changed. In FIGS. 6A and 6B, an array cavity layer 30 is configured with the first transparent layer 13, the second transparent layer 14, the third transparent layer 15, and the transparent electrode layer 16. The light emitting function layer 31 is configured with the hole injection layer and hole transport layer 17, the emitting layer 18, and the electron transport layer 19.

As illustrated in FIG. 6A, when the light emitting function layer 31 is thick, and the array cavity layer 30 is thin, a blue resonance component is extracted in addition to the red resonance component. This is because since the optical distance is obtained by the product of the film thickness and the refractive index, if the light emitting function layer 31 having a higher refractive index on the shorter wavelength side becomes thick, the entire optical distance of the component on the shorter wavelength side becomes long and the resonance wavelength on the shorter wavelength side becomes long. As a result, the blue light emitting component is extracted.

However, as illustrated in FIG. 6B, when the light emitting function layer 31 is thin, and the array cavity layer 30 is thick, the entire optical distance of the components on the shorter wavelength side becomes short, and the extracted light emitting components except for the red component are shifted to the shorter wavelength side, as a result. Accordingly, the blue light emitting component is not easily extracted, and the red pixel can exhibit a wide color gamut.

In the embodiment, if an optical distance between the emitting layer 18 side of the reflecting layer 12 and the emitting layer 18 side of the counter electrode 20 is D(λ), a phase shift in the reflection on the reflecting layer 12 is φ_{L}(λ), a phase shift in the reflection on the counter electrode 20 is φ_{U}(λ), the resonance peak wavelength is λ, and an integer is m, the structure satisfies the following equation.

D(λ)={(2πm+φ_{L}(λ)+φ_{U}(λ))/4π}λ (5)

Here, the phase shift φ_{L}(λ) in the reflection of the reflecting layer 12 and the phase shift φ_{U}(λ) in the reflection of the counter electrode 20 are changed according to wavelengths.

D(λ) is an optical distance between the reflecting layer 12 and the counter electrode 20, but is an optical distance that changes according to wavelengths. That is, D(λ) is represented by the following equation.

D(λ)=n₁(λ)*d₁+n₂(λ)*d₂+ . . . nₖ(λ)*dₖ (6)

In Equation (6), nₖ(λ) is a refractive index of the k-th layer, and dₖ is a film thickness of the k-th layer.

Here, if a resonance peak wavelength of a long wavelength component in the red pixel, that is, the red light emitting resonance peak wavelength is λ_{LC}, Equation (5) described above can be substituted as below.

D(λ_{LC})={(2πm+φ_{L}(λ_{LC})+φ_{U}(λ_{LC}))/4π}λ_{LC} (7)

Equation (6) described above can be modified as follows.

λ_{LC}=D(λ_{LC})/{(2πm+φ_{L}(λ_{LC})+φ_{U}(λ_{LC}))/4π} (8)

Also, Equation (6) can be applied to Equation (8) as follows.

λ_{LC}={n₁(λ_{LC})*d₁+n₂(λ_{LC})*d₂+ . . .

nₖ(λ_{LC})*dₖ}/{(2πm+φ_{L}(λ_{LC})+φ_{U}(λ_{LC}))/4π} (9)

In Equation (9), red emission light having the resonance peak wavelength λ_{LC} can be extracted by setting m=1, and adjusting a value of D(λ_{LC}), that is, the film thickness of the transparent layer and the film thickness of the light emitting function layer so that a desired red light emitting resonance peak wavelength λ_{LC} is obtained.

However, a red light emitting output wavelength λ_{LOUT} actually output from the light emitting device U1 is obtained as a wavelength at a position in which the product of the emission intensity of an inside light emitting peak wavelength λ_{LIN} inside of the light emitting function layer and the emission intensity of the resonance peak wavelength λ_{LC} reaches the peak.

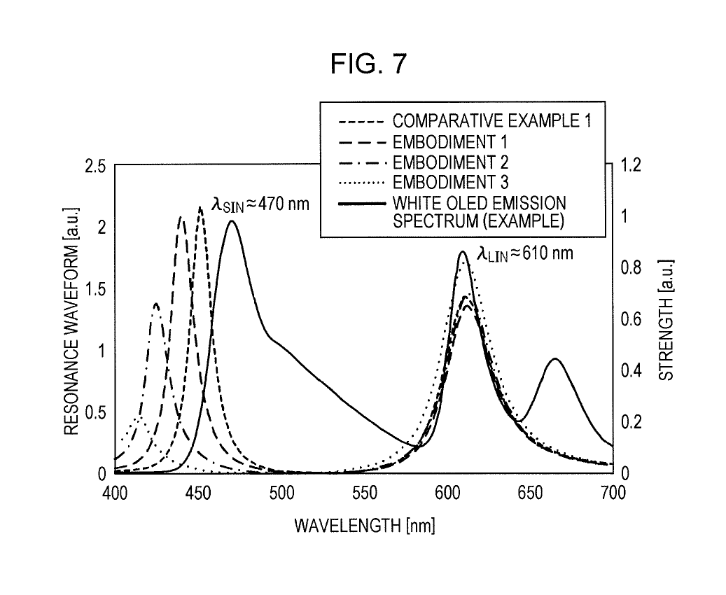

FIG. 7 is a diagram illustrating an emission spectrum inside the white light emitting function layer 31 configured with the hole injection layer and hole transport layer 17, the emitting layer 18, and the electron transport layer 19, and simulation results of resonance spectrums according to Comparison example 1, and Examples 1 to 3. As illustrated in FIG. 7, the light emitting peak wavelength λ_{LIN} on the long wavelength side inside the light emitting function layer 31 is about 610 nm. Accordingly, in order to cause the red light emitting output wavelength λ_{LOUT} to be about 610 nm, the film thickness of the transparent layer and the film thickness of the light emitting function layer are adjusted so that the red light emitting resonance peak wavelength λ_{LC} and the red light emitting light emitting peak wavelength λ_{LIN} are substantially identical to each other. As a result, the red light can be effectively extracted.

Next, if the resonance peak wavelength of the short wavelength component in the red pixel is λ_{SC}, Equation (5) described above is substituted as follows.

D(λ_{SC})={(2π(m+1)+φ_{L}(λ_{SC})+φ_{U}(λ_{SC}))/4π}λ_{SC} (10)

If the resonance degree in Equation (10) is m+1, and the resonance degree m is 1 in Equation (7), the resonance degree in Equation (10) is m+1=2.

Equation (10) described above is modified as follows.

λ_{SC}=D(λ_{SC})/{(2π(m+1)+φ_{L}(λ_{SC})+φ_{U}(λ_{SC}))/4π} (11)

Also, Equation (6) is applied to Equation (11) as follows.

λ_{SC}={n₁(λ_{SC})*d₁+n₂(λ_{SC})*d₂+ . . . nₖ(λ_{SC})*dₖ}/{(2π(m+1)+φ_{L}(λ_{SC})+φ_{U}(λ_{SC}))/4π} (12)

Based on Equation (12), if m+1=2 is set, and the resonance peak wavelength λ_{SC} on the short wavelength side is calculated when the film thickness of the transparent layer and the film thickness of the light emitting function layer are the film thickness according to Comparison example 1, the resonance peak wavelength λ_{SC} becomes 440 nm.

The light emitting peak wavelength λ_{SIN} on the short wavelength side inside the white light emitting function layer 31 is about 470 nm as illustrated in FIG. 7. The output wavelength λ_{SOUT} on the short wavelength side is obtained as a wavelength at a position in which the product of the emission intensity of the light emitting peak wavelength λ_{SIN} on the short wavelength side inside the light emitting function layer and the emission intensity of the resonance peak wavelength λ_{SC} on the short wavelength side reaches the peak. As a result, the output wavelength λ_{LOUT} on the short wavelength side according to Comparison example 1 becomes a wavelength having the peak of 460 nm to 470 nm. FIG. 4 is a diagram illustrating the output wavelength λ_{SOUT} on the short wavelength side according to Comparison example 1. As illustrated in FIG. 4, in the case of Comparison example 1, the emission intensity of the wavelength having 460 nm to 470 nm as the peak is as high as about 0.9, and the ratio to the red light intensity is also great. Accordingly, it is discovered that the color purity of the red pixel is deteriorated by extracting a component in a color close to blue.

Meanwhile, based on Equation (12), if m+1=2 is set, and the resonance peak wavelength λ_{SC} on the short wavelength side is calculated when the film thickness of the transparent layer and the film thickness of the light emitting function layer are the film thicknesses according to Examples 1 to 3, the resonance peak wavelength λ_{SC} on the short wavelength side according to Example 1 is 440 nm, the resonance peak wavelength λ_{SC} on the short wavelength side according to Example 2 is 426 nm, and the resonance peak wavelength λ_{SC} on the short wavelength side according to Example 3 is 412 nm. The resonance spectrums according to Examples 1 to 3 are illustrated in FIG. 7. As clearly illustrated in FIG. 7, it is discovered that the resonance peak wavelength is shifted to the short wavelength side compared to Comparison example 1.

Inside the white light emitting function layer 31, as illustrated in FIG. 7, the intensity near the range of 412 nm to 440 nm is extremely low. The output wavelengths λ_{SOUT} on the short wavelength side according to Examples 1 to 3 are calculated as wavelengths at a position in which the product of the emission intensity of the light emitting peak wavelength λ_{SIN} on the short wavelength side inside the light emitting function layer and the emission intensity of the resonance peak wavelength λ_{SC} on the short wavelength side reaches the peak.

That is, according to Examples 1 to 3, the output wavelength λ_{SOUT} on the short wavelength side is about 430 nm to 460 nm as illustrated in FIG. 4, but the emission intensity is extremely low. The emission intensity is about 0.2 in Example 1 having the highest emission intensity and is about 15% to the emission intensity of the red output wavelength λ_{LOUT} on the long wavelength side. As a result, in Examples 1 to 3, the short wavelength component is not easily extracted, and the color purity of the red pixel is not deteriorated.

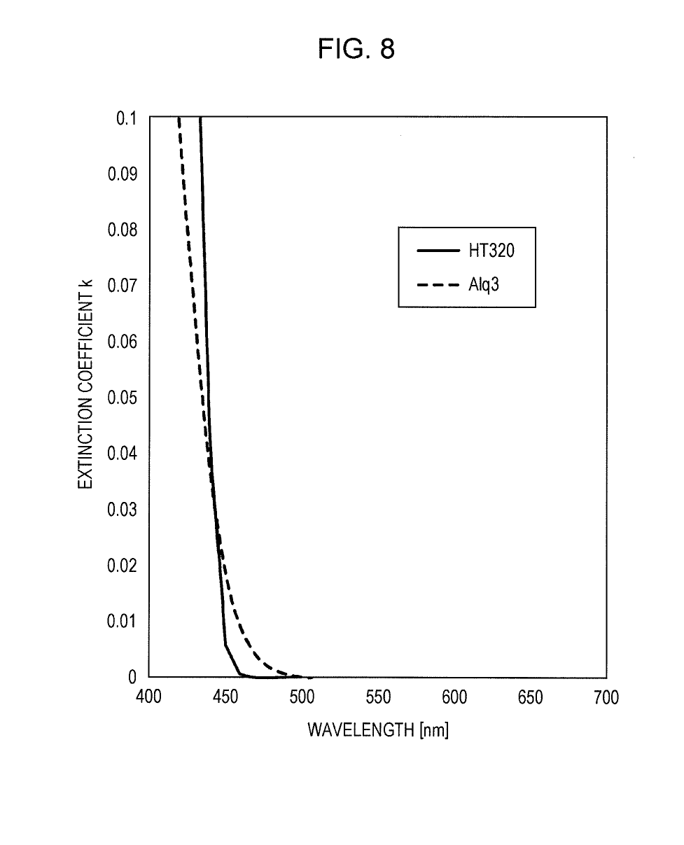

Furthermore, as illustrated in FIG. 8, about 450 nm is set as a border, and light having a shorter wavelength than 450 nm has an extinction coefficient drastically increasing in the light emitting function layer such as HT-320 or Alq3. Therefore, if a resonance peak wavelength λ_{c} is set within the scope as above, the light on the reflecting layer 12 and the counter electrode 20 are absorbed while reflection repeats. Accordingly, as the resonance peak wavelength λ_{SC} on the short wavelength side is shifted to the short wavelength side, the intensity of the resonance spectrum also decreases. As examined above, since the output wavelength λ_{OUT} is obtained as the product of the emission intensity of the inside emitted light and the intensity of the resonance spectrum, if the intensity of the resonance peak wavelength λ_{SC} on the short wavelength side decreases, the extracted short wavelength component becomes small. According to this, color purity of the red pixel can be increased.

As described above, it is discovered that the deterioration of the color purity of the red pixel can be prevented by adjusting the film thickness of the transparent layer and the film thickness of the light emitting function layer so that the emission intensity of the output wavelength λ_{SOUT} on the short wavelength side obtained as the product of emission intensity of the emission spectrum on the short wavelength side inside the light emitting function layer causing the light emitting peak wavelength to be the wavelength λ_{SIN} and the emission intensity of the emission spectrum on the short wavelength side by the resonance causing the resonance peak wavelength to be the wavelength λ_{SC} becomes about 15% of the emission intensity of the output wavelength λ_{LOUT} on the long wavelength side.

In the example described above, it is found that the emission intensity of the output wavelength λ_{SOUT} on the short wavelength side becomes about 15% of the emission intensity of the output wavelength λ_{LOUT} on the long wavelength side by adjusting the film thickness of the transparent layer and the film thickness of the light emitting function layer, so that the resonance peak wavelength λ_{SC} on the short wavelength side is smaller than the light emitting peak wavelength λ_{SIN} inside the light emitting function layer by about 30 nm.

According to the embodiment, it is possible to provide a light emitting apparatus having good color reproductivity without using a color filter. As a result of comparing a case of using the color filter in the light emitting apparatus according to the embodiment, and a case of not using the color filter, the brightness of the white color of the light emitting apparatus in the case of not using the color filter is enhanced by 30%.

### D: Modification Example

The invention is not limited to the embodiments described above, and various modifications described below are possible. Also, it is obvious that respective modifications and embodiments may be appropriately combined.

### 1. Modification Example 1

In the embodiment as described above, an example of not using a color filter is described, but it may be configured so that a color filter is formed. If a color filter for a red pixel has transmittance of a short wavelength component is to be high to a certain degree, broad color purity can be realized by using the light emitting apparatus according to the invention as described above. As a result, it is possible to expand the selection scope of the color filter material. Also, it is possible to cause the film thickness of the color filter to be thin.

### 2. Modification Example 2

Since the sharpness of the resonance peak waveform changes according to the reflectivity or the film thickness of the counter electrode 20 as a translucent transflective layer, how much the resonance peak wavelength λ_{SC} on the short wavelength side is to be decreased more than the light emitting peak wavelength λ_{SIN} inside the light emitting function layer may be determined according to the sharpness.

### 3. Modification Example 3

In the embodiments described above, an example of applying the invention to a top emission-type light emitting apparatus that extracts light from a second substrate side formed on the sealing layer 21 is described. However, the invention is not limited to the example described above. For example, it is possible to apply the invention to a bottom emission-type light emitting apparatus that extracts light from the first substrate formed on the reflecting layer 12.

### E: Application Example

The light emitting apparatus according to the invention can be applied to various electronic apparatuses. Hereinafter, it is described with respect to representative application examples.

### 1. Application Example 1

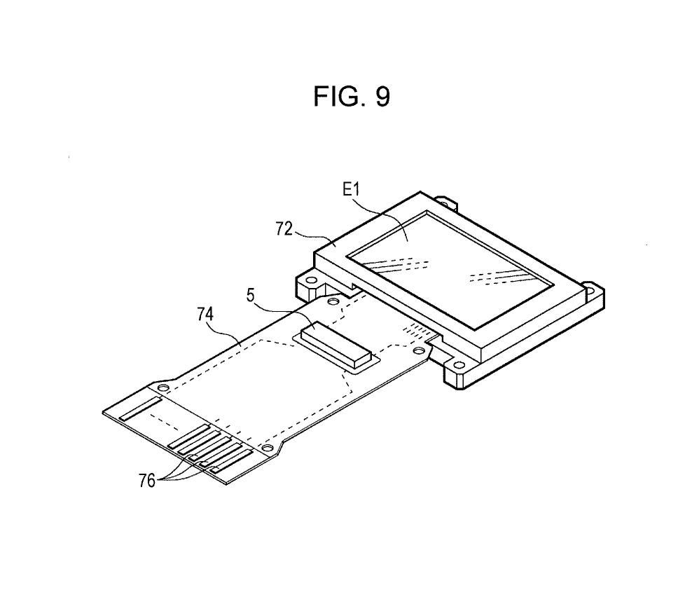

FIG. 9 is a perspective view illustrating an example of applying the light emitting apparatus E1 according to the embodiment described above, to a micro display displaying an image in a head-mounted display. The light emitting apparatus E1 is stored in a frame-shaped case 72 opened on the display unit, and one end of a Flexible Printed Circuits (FPC) substrate 74 is connected to the light emitting apparatus E1. A control circuit 5 of a semiconductor chip is mounted on the FPC substrate 74 by Chip On Film (COF) technology, and a plurality of terminals 76 are provided and connected to a higher circuit (not illustrated). Image data is supplied from the higher circuit through the plurality of terminals 76 in synchronization with synchronization signals. The synchronization signals include a vertical synchronizing signal, a horizontal synchronizing signal, and a dot clock signal. Also, in the image data, a gradation level of a pixel of an image to be displayed is regulated to be, for example, 8 bits.

The control circuit 5 uses the both functions of a power supply circuit of the light emitting apparatus E1 and the data signal output circuit. That is, the control circuit 5 supplies various control signals and various potentials generated by the synchronization signals to the light emitting apparatus E1, and converts digital image data into analog data signals to be supplied to the light emitting apparatus E1.

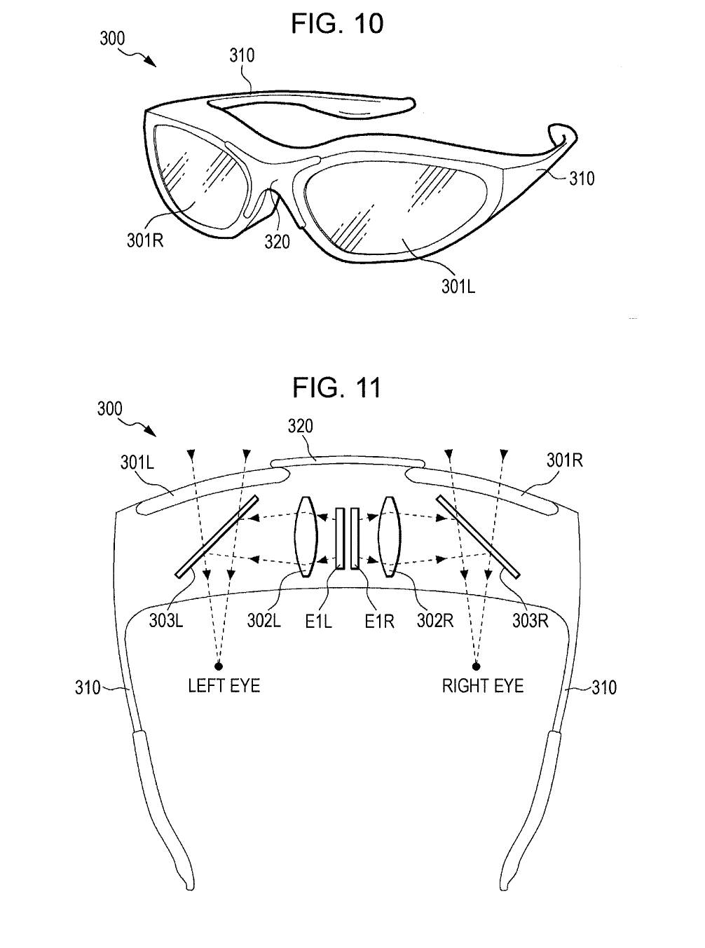

FIG. 10 is a diagram illustrating an appearance of a head-mounted display 300, and FIG. 11 is a diagram illustrating an optical configuration. As illustrated in FIG. 10, the head-mounted display 300 has a temple 310, a bridge 320, and lenses 301L and 301R, externally similar to general glasses. Also, as illustrated in FIG. 11, the head-mounted display 300 is provided with the light emitting apparatus E1L for a left eye and the light emitting apparatus E1R for a right eye on the inner side (lower side in the drawing) of the lenses 301L and 301R near the bridge 320.

The image display surface of the light emitting apparatus E1L is disposed on the left in FIG. 11. According to this, the display image by the light emitting apparatus E1L is output in a 9 o'clock direction in the drawing, through an optical lens 302L. A half mirror 303L reflects a display image by the light emitting apparatus E1L in a 6 o'clock direction, and also causes light incident from a 12 o'clock direction to penetrate.

The image display surface of the light emitting apparatus E1R is disposed on the right side opposite to the light emitting apparatus E1L. According to this, the display image of the light emitting apparatus E1R is output in a 3 o'clock direction in the drawing, through an optical lens 302R. A half mirror 303R reflects the display image by the light emitting apparatus E1R in a 6 o'clock direction, and also causes the light incident from the 12 o'clock direction to penetrate.

In this configuration, a wearer of the head-mounted display 300 can observe display images by the light emitting apparatus E1L, E1R in a see-through state of being overlapped with regard to external appearance. Also, in the head-mounted display 300, among binocular images accompanying parallax, if an image for a left eye is displayed on the light emitting apparatus E1L and an image for a right eye is displayed on the light emitting apparatus E1R, it is possible to cause the wearer to perceive the displayed image as if the image has depth and stereoscopic visibility (3D display).

The highly bright light emitting apparatus E1 that has broad color purity can be appropriately used for the head-mounted display 300 that requires brightness as a main characteristic. Also, since the light emitting apparatus E1 is small in size and high in definition, the light emitting apparatus E1 can be appropriately used for a small apparatus such as the head-mounted display 300.

Further, in addition to the head-mounted display 300, the light emitting apparatus E1 can be applied to an electronic view finder for a video camera, a lens exchanging-type digital camera, or the like.

### 2. Application Example 2

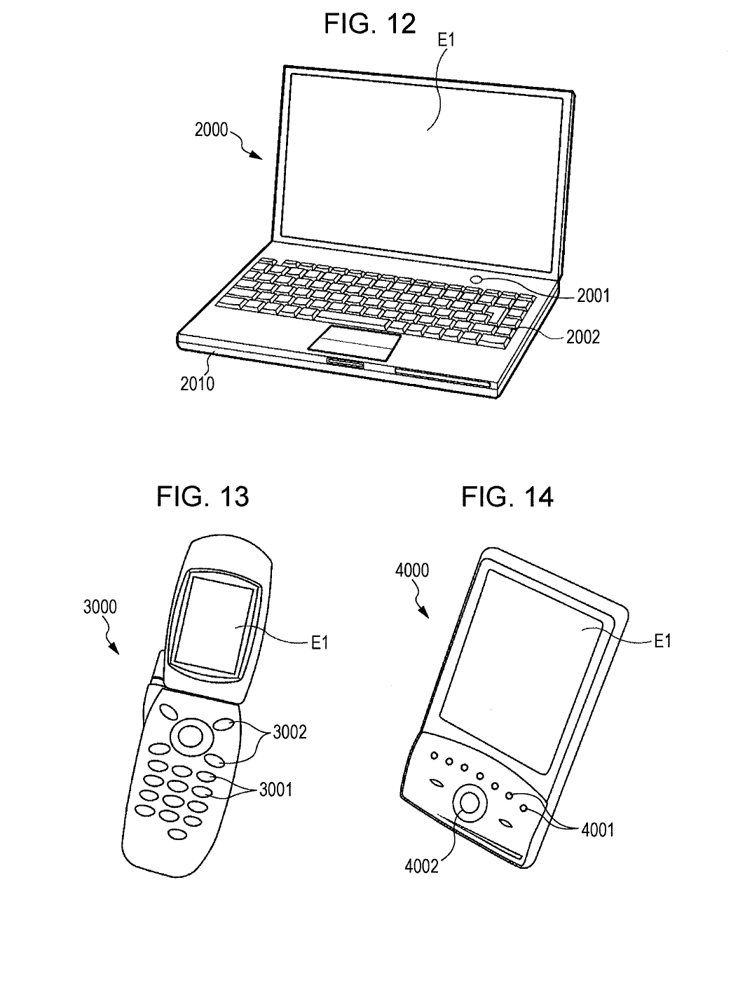

FIG. 12 is a perspective view illustrating a configuration of a mobile personal computer to which the light emitting apparatus E1 according to the embodiment described above is applied as a display apparatus. A personal computer 2000 includes the light emitting apparatus E1 as a display apparatus and a main body 2010. The main body 2010 is provided with a power switch 2001 and a keyboard 2002. Since the light emitting apparatus E1 uses an organic EL device, the viewing angle is wide and an image can be easily displayed.

FIG. 13 is a diagram illustrating a cellular phone to which the light emitting apparatus E1 according to the embodiment described above is applied. A cellular phone 3000 includes a plurality of operation buttons 3001, a scroll button 3002, and the light emitting apparatus E1 as a display device. A screen displayed on the light emitting apparatus E1 is scrolled by operating the scroll button 3002.

FIG. 14 is a configuration of a portable information terminal (a Personal Digital Assistant (PDA) or a smart phone) to which the light emitting apparatus E1 according to the embodiment described above is applied. A portable information terminal 4000 includes a plurality of operation buttons 4001, a power switch 4002, and the light emitting apparatus E1 as a display device. If the power switch 4002 is operated, various items of information such as an address book or a scheduler are displayed on the light emitting apparatus E1.

Further, in addition to the configurations illustrated in FIGS. 9 to 14, an electronic apparatus to which the light emitting apparatus according to the embodiment described above is applied can include an apparatus including a digital camera, a television, a video camera, a navigation device, a pager, an electronic organizer, an electronic paper, a calculator, a word processor, a workstation, a video telephone, a POS terminal, a printer, a scanner, a copying machine, a video player, and a touch panel, or the like.

The entire disclosure of Japanese Patent Application No. 2013-176381, filed Aug. 28, 2013 is expressly incorporated by reference herein.

What is claimed is:

1. A light emitting apparatus comprising:
a reflecting layer;
an array cavity layer that includes a transparent layer disposed on the reflecting layer and a transparent electrode layer disposed on the transparent layer;
an emitting layer disposed on the array cavity layer; and
a translucent reflecting layer disposed on the emitting layer,
wherein the light emitting apparatus has a resonance structure for adjusting an optical path length between the reflecting layer and the translucent reflecting layer for each emission region, and the emitting layer performs internal luminescence with a first wavelength region and a second wavelength region on a short wavelength side with respect to the first wavelength region,
wherein when a light emitting peak wavelength of the first wavelength region in the internal luminescence is λ_{LIN}, the resonance peak wavelength of the first wavelength region in the resonance is λ_{LC}, and an output wavelength of the first wavelength region is λ_{LOUT},
a light emitting peak wavelength of the second wavelength region in the internal luminescence is λ_{SIN}, a resonance peak wavelength of the second wavelength region in the resonance is λ_{SC}, and an output wavelength of the second wavelength region is λ_{SOUT},
the light emitting peak wavelength λ_{LIN} of the first wavelength region, the resonance peak wavelength λ_{LC} of the first wavelength region, and the output wavelength λ_{LOUT} of the first wavelength region are substantially identical, and
the light emitting peak wavelength λ_{SIN} of the second wavelength region, the resonance peak wavelength λ_{SC} of the second wavelength region, and the output wavelength λ_{SOUT} of the second wavelength region satisfy a relationship of
light emitting peak wavelength λ_{SIN}>output wavelength λ_{SOUT}>resonance peak wavelength λ_{SC}, and
wherein film thicknesses of the array cavity layer and the emitting layer are adjusted so that an emission intensity of the output wavelength λ_{SOUT} represented by a product of an emission intensity of the light emitting peak wavelength λ_{SIN} and an emission intensity of the resonance peak wavelength λ_{SC} is equal to or less than 15% of an emission intensity of the output wavelength λ_{LOUT}.

2. The light emitting apparatus according to claim 1,
wherein when an optical path length of the translucent reflecting layer from the reflecting layer is D(λ), a phase shift in reflection on the reflecting layer is φ_{L}(λ), a phase shift in reflection on the translucent reflecting layer is φ_{U}(λ), a peak wavelength of a standing wave generated between the reflecting layer and the translucent reflecting layer is λ, and an integer equal to or smaller than 2 is m,
the resonance peak wavelength λ_{LC} of the first wavelength region satisfies
λ_{LC}=D(λ_{LC})/{2πm+φ_{L}(λ_{LC})+φ_{U}(λ_{LC}))/4π},
the resonance peak wavelength λ_{SC} of the second wavelength region satisfies
λ_{SC}=D(λ_{SC})/{(2π(m+1)+φ_{L}(λ_{SC})+φ_{U}(λ_{SC}))/4π}, and
when a predetermined constant is B, the resonance peak wavelength λ_{SC} and the light emitting peak wavelength λ_{SIN} satisfy
resonance peak wavelength λ_{SC}≦light emitting peak wavelength λ_{SIN}−B.

3. The light emitting apparatus according to claim 2,
wherein with respect to the resonance peak wavelength λ_{LC} and the resonance peak wavelength λ_{SC}, the optical path length D(λ_{LC}) and the optical path length D(λ_{SC}) are adjusted so that the integer m becomes 1 in equations of the optical path length D(λ_{LC}) and the optical path length D(λ_{SC}).

4. The light emitting apparatus according to claim 2,
wherein the constant B is set to 30 nm.

5. The light emitting apparatus according to claim 1,
wherein an extinction coefficient in the emitting layer is equal to or greater than 0.02 in the resonance peak wavelength λ_{SC}.

6. The light emitting apparatus according to claim 1,
wherein the resonance peak wavelength λ_{SC} is equal to or less than 450 nm.

7. An electronic apparatus comprising the light emitting apparatus according to claim 1.

8. An electronic apparatus comprising the light emitting apparatus according to claim 2.

9. An electronic apparatus comprising the light emitting apparatus according to claim 3.

10. An electronic apparatus comprising the light emitting apparatus according to claim 4.

11. An electronic apparatus comprising the light emitting apparatus according to claim 5.

12. An electronic apparatus comprising the light emitting apparatus according to claim 6.

13. The electronic apparatus according to claim 7, further comprising an optical member between an emitting surface of the light emitting apparatus and a display surface of the electronic apparatus.
